(19) United States
(12) Patent Application Publication
(10) Pub. No.: US 2017/0134048 A1
(43) Pub. Date: May 11, 2017

(54) MESSAGE-PASSING BASED DECODING USING SYNDROME INFORMATION, AND RELATED METHODS

(71) Applicant: SAMSUNG ELECTRONICS CO., LTD., SUWON-SI (KR)

(72) Inventors: GUY INBAR, RAMAT GAN (IL); MOSHE TWITTO, RAMAT GAN (IL); ERAN HOF, RAMAT GAN (IL); JUN JIN KONG, YONGIN-SI (KR)

(21) Appl. No.: 14/937,379

(22) Filed: Nov. 10, 2015

(51) Int. Cl. H03M 13/11; H03M 13/00

(52) U.S. Cl. CPC H03M 13/1125; H03M 13/616

(57) ABSTRACT

A decoding method for an iterative message-passing based decoder, such as a low-density parity-check (LDPC) decoder, includes calculating syndrome information for a received word, and initializing variable nodes based on the received word. Each received bit of the received word may be represented by a Likelihood-Ratio (LR) or Log-Likelihood-Ratio (LLR) at a respective variable node. Further, the method includes iteratively updating check nodes, and updating the LRs of variable nodes using the syndrome information, determining an error vector from the LRs of the variable nodes, and determining a transmitted word, corresponding to the received word, by subtracting the error vector from the received word. The syndrome information is calculated based upon a parity check matrix.

### BACKGROUND

The inventive concept is generally directed to decoding, and more particularly, to communication channel decoding, for example, low-density parity-check (LDPC) decoding in semiconductor memories.

In the field of digital communications, errors generated due to noise may be corrected by using a coding and decoding technology based on error correction codes. Among the error correction codes, an LDPC code is an error correction code using a probability-based repeated calculation.

A goal of digital communication is to achieve the reliable transfer of data over a noisy channel. Examples of such channels are copper wires, optical fibers, wireless communication channels, storage media and computer buses. FIG. 1. illustrates a general digital communication approach. Information is sent to an encoder which may alter the information and add additional data (e.g. sometimes called parity) to generate a codeword. The codeword is then sent via the channel. The received codeword at the channel output may be different from the original codeword due to the noisy channel. The received codeword is the input to the decoder which, based on the additional data added by the encoder (parity), tries to recover the original information. Reliable communication is achieved were the decoder output, the recovered information, matches the original information. The channel is characterized by its capacity, which is the maximum rate at which information can be reliably transmitted over the channel.

LDPC codes are a class of linear block codes with an implementable decoder, which provide near-capacity performance and therefore are widely used for data-transmission and data-storage. The code is defined by an LDPC matrix that facilitates iterative decoding and provides near-optimal performance.

Such an LDPC decoder is based on the Message-Passing principal. In the decoding process each received bit may be represented by its Likelihood-Ratio (LR) or by its Log-Likelihood-Ratio (LLR), and the decoder iteratively updates the LLR's based on the parity check equations.

Decoder performance may be measured by: an average iteration count, which is the average number of iterations needed for successful decoding; Frame Error Rate (FER) which is the probability for decoding failure; and output latency which is the total decoding time.

Generally, as illustrated in FIG. 1, within the context of digital communication systems, there is a first communication device at one end of a communication channel with encoding capability and a second communication device at the other end of the communication channel with decoding capability. In many instances, one or both of these two communication devices includes encoding and decoding capability (e.g., within a bi-directional communication system). LDPC codes can be applied in various digital communication channel environments, and a variety of additional applications as well, including those that use some form of data storage (e.g., hard disk drive (HDD) applications and other memory storage devices) in which data is encoded before writing to the storage media, and then the data is decoded after being read/retrieved from the storage media.

LDPC codes and turbo codes rely on interleaving messages inside an iterative process. LDPC codes are represented by bipartite graphs, often called Tanner graphs, in which one set of nodes, the variable nodes, corresponds to bits of the codeword and the other set of nodes, the check nodes, sometimes called constraint nodes, correspond to the set of parity-check constraints which define the code. Edges in the graph connect variable nodes to check nodes. A variable node and a constraint node are said to be neighbors if they are connected by an edge in the graph. To each variable node is associated one bit of the codeword.

A bit sequence associated one-to-one with the variable node sequence is a codeword of the code if and only if, for each check node, the bits neighboring the constraint (via their association with variable nodes) sum to zero modulo two, i.e., they include an even number of ones.

The decoders and decoding processes used to decode LDPC codewords operate by exchanging messages within the graph along the edges and updating these messages by performing computations at the nodes based on the incoming messages. Such decoding will be generally referred to as message passing based decoding. Each variable node in the graph is initially provided with a soft bit, termed a received value, which indicates an estimate of the associated bit's value and reliability as determined by observations from, e.g., the communications channel. A collection of received values constitutes a received word. The number of edges attached to a node, i.e., a variable node or constraint node, is referred to as the degree of the node.

In many such prior art communication devices, one of the greatest hurdles and impediments in designing effective devices and/or communication devices that can decode LDPC coded signals is the typically large area and memory required to store and manage all of the updated bit edge messages and check edge messages that are updated and employed during iterative decoding processing (e.g., when storing and passing the check edges messages and the bit edges messages back and forth between a check engine and a bit engine, respectively). When dealing with relatively large block sizes in the context of LDPC codes, the memory requirements and memory management need to deal with these check edges messages and bit edges messages can be very difficult to handle.

### SUMMARY

An objective of the present inventive concept is to reduce the power consumption and total gate count for a hardware implemented LDPC decoder.

This may be done by an appropriate utilization of the syndrome information which reduces the dynamic range necessary for successful decoding.

Specifically, the number of bits for LR or LLR representation (and the corresponding logic) can be reduced without performance penalty (e.g. by reducing LR representation from 5 bits to 4 bits).

Additionally, due to a statistical characteristic of the present decoder data, the hardware toggling rate is reduced or minimized.

Performance (iteration count, Frame-Error-Rate and output latency) of the present decoder is not reduced compared to a conventional LDPC decoder.

According to an aspect of the inventive concepts an embodiment is directed to a decoding method for an iterative message-passing based decoder. The method includes calculating syndrome information for a received word, and initializing variable nodes based on the received word. Each received bit of the received word may be represented by a Likelihood-Ratio (LR) or Log-Likelihood-Ratio (LLR) at a respective variable node. Further, the method includes iteratively updating check nodes, and updating the LRs of variable nodes using the syndrome information, determining an error vector from the LRs of the variable nodes, and determining a transmitted word, corresponding to the received word, by subtracting the error vector from the received word. It is noted that the term “error vector” corresponds to an indication of the error's position in a received codeword (not to be confused with decoding error).

The received word is associated with parity check matrix (the parity check matrix is a property of the encoder). The syndrome information may be derived using the parity check matrix. In various embodiments, the syndrome information (S) may be calculated based upon S=Hy, where y is a received vector and H is the parity check matrix, and the computation is over GF(2).

In various embodiments, LRs of the variable nodes indicate the likelihood of an error. In certain embodiments, an asymmetric dynamic range is used to characterize the LRs, and/or a non-uniform quantization technique is used to characterize the LRs. Also, a variable length coding technique may be used to characterize the LRs.

According to another aspect of the inventive concepts an embodiment is directed to a low-density parity-check (LDPC) decoding method for an iterative message-passing based decoder. The method includes calculating syndrome information for a received word from an associated parity check matrix, initializing variable nodes based on the received word, and iteratively updating check nodes, and updating variable nodes using the syndrome information. The method includes determining an error vector from the variable nodes, and determining a transmitted word, corresponding to the received word, by subtracting the error vector from the received word.

According to another aspect of the inventive concepts an embodiment is directed to a message-passing based decoder comprising a memory configured to store states of variable nodes and check nodes in a bipartite graph, and a logic device module connected to the memory and configured to perform calculations for exchanging messages between the check nodes and the variable node. A control device is configured to control the logic device module to perform the message exchanging process between the check nodes and the variable nodes based on the bipartite graph, including calculating syndrome information for a received word, initializing variable nodes based on the received word with each received bit of the received word being represented by a Likelihood-Ratio (LR) at a respective variable node, iteratively updating check nodes, and updating the LRs of variable nodes using the syndrome information, determining an error vector from the LRs of the variable nodes, and determining a transmitted word, corresponding to the received word, by subtracting the error vector from the received word.

The received word is associated with a parity check matrix, and wherein the syndrome information (S) is calculated based upon S=Hy, where y is a received vector and H is the parity check matrix, and the computation is over GF(2). LRs of the variable nodes indicate the likelihood of an error. An asymmetric dynamic range may be used to characterize the LRs, a non-uniform quantization technique may be used to characterize the LRs and/or a variable length coding technique may be used to characterize the LRs.

### BRIEF DESCRIPTION OF THE DRAWINGS

The above and other aspects and features of the inventive concept will become readily understood from the detailed description that follows, with reference to the accompanying drawings, in which:

FIG. 1 is a block diagram of a typical digital communication approach according to the prior art;

FIG. 2 is a schematic block diagram of a message-passing decoder in accordance with an example embodiment of the present inventive concept;

FIG. 3 is a flowchart illustrating various method steps in accordance with a conventional decoding process;

FIGS. 4-9 are bipartite graphs illustrating node updating in a conventional decoding process;

FIG. 10 is a flowchart illustrating various method steps in accordance with an example embodiment having features of the present inventive concept;

FIGS. 11-16 are bipartite graphs illustrating node updating in accordance with an example embodiments of the present inventive concept; and

FIG. 17 is a graph illustrating the LLR distribution for a conventional decoder, and for a decoder with features of the present inventive concept.

### DETAILED DESCRIPTION OF EMBODIMENTS

Embodiments of the inventive concept are described below with reference to the accompanying drawings. These embodiments are presented as teaching examples and should not be construed to limit the scope of the inventive concept.

In the description that follows, the terms first, second, etc. may be used to describe various elements, but these elements should not be limited by these terms. Rather, these terms are used merely to distinguish one element from another. For example, a first element could be termed a second element, and, similarly, a second element could be termed a first element, without departing from the scope of this disclosure. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

The notion of message passing algorithms implemented on graphs is more general than LDPC decoding. The general view is a graph with nodes exchanging messages along edges in the graph and performing computations based on incoming messages in order to produce outgoing messages.

LDPC decoding operations generally comprise message passing processes. There are many potentially useful message passing processes and the use of such processes is not limited to LDPC decoding. The current invention can be applied in the context of virtually any such message passing processes and therefore can be used in various message passing systems of which LDPC decoders are but one example.

Also, the description mostly refers to LLR based decoders (as it is the more common implementation), however the embodiments herein can be applied to an LR based decoder, as would be appreciated by those skilled in the art.

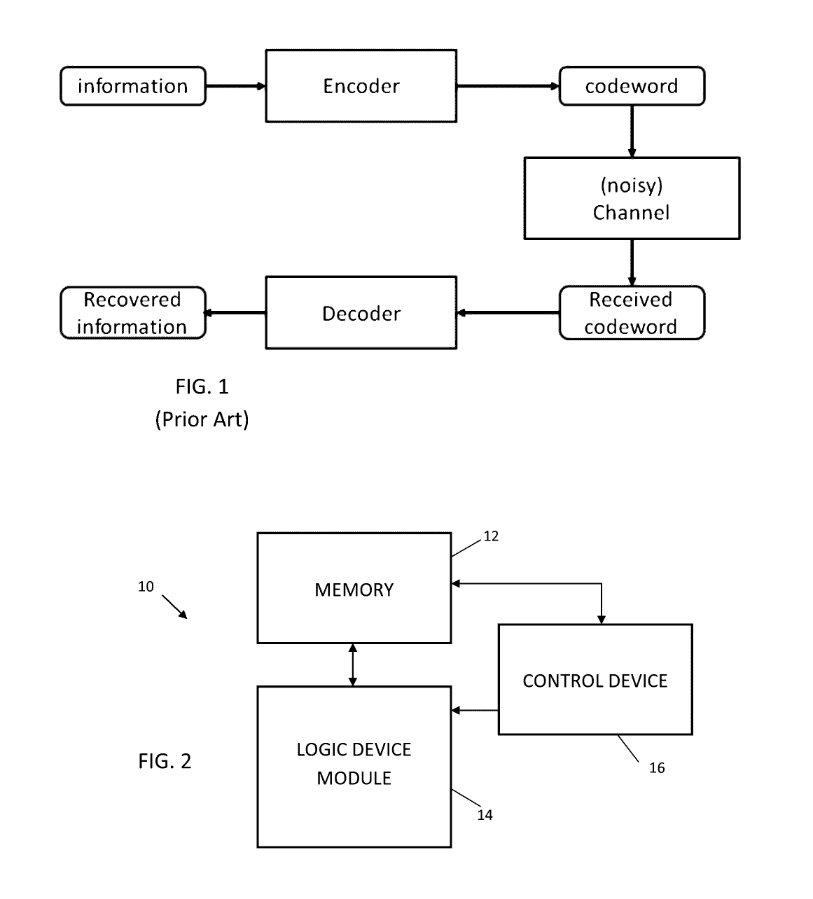

A message-passing based decoder 10 is illustrated in FIG. 2. The message-passing decoder may be used in a communication system that uses LDPC codes, for example, as illustrated in FIG. 1 and discussed above. As such, in communication systems that use LDPC codes, there may be a first communication device at one end of a communication channel with encoding capability and a second communication device at the other end of the communication channel with decoding capability. The communication devices may also include both encoding and decoding capability (e.g., within a bi-directional communication system). LDPC codes can be applied in a variety of additional applications including memory storage devices, in which data is encoded before writing to the storage media, and then the data is decoded after being read/retrieved from the storage media.

LDPC codes rely on interleaving messages inside an iterative process. LDPC codes are represented by bipartite graphs, e.g. Tanner graphs, in which the variable nodes correspond to bits of the codeword, and the check nodes correspond to the set of parity-check constraints which define the code. Edges in the graph connect variable nodes to check nodes.

The messaging-passing based decoder 10 may be an LDPC decoder as discussed above. The message-passing decoder 10 includes a memory 12 configured to store states of variable nodes V and check nodes C in a bipartite graph, and a logic device module 14 connected to the memory 12 and configured to perform calculations for exchanging messages between the check nodes C and the variable nodes V. A control device 16 is configured to control the logic device 14 module to perform the message exchanging process between the check nodes C and the variable nodes V based on the bipartite graph.

The memory 12 stores states of variable nodes, and stores states of the check nodes, in the LDPC bipartite graph. The memory 12 may be made up of a plurality of memory devices. Also, the memory 12 may include a plurality of memory sectors that are partitioned, and each of the memory sectors may be allocated to one or more variable nodes, or one or more check nodes.

The logic device module 14 may include logic circuits that are respectively connected to the memory 12 for performing calculations for exchanging messages between the check nodes C and the variable nodes V.

The control device 16 controls the logic device module 14 to perform the message exchange between the check nodes C and the variable nodes V based on scheduling information obtained by manipulating the LDPC bipartite graph. The scheduling information may be determined so as to satisfy conditions under which the memory access collisions and read-before-write violations do not occur in the memory during the message exchange between the check nodes C and the variable nodes V.

According to the message exchange process, the variable nodes and check nodes may be updated in the memory 12.

The control device 16 performs the LDPC decoding process based on results of the variable node update according to the message exchange. For example, the control device 16 reads the states of the updated variable nodes V from the memory 12 to perform a tentative decoding process, and after that, determines whether there are errors in the received codeword. As an example, the control device 16 may determine whether there is an error in the received codeword based on hard decision of the states of the variable nodes V.

If it is determined there is an error in the received codeword, the control device 16 flips the corresponding bit of the received codeword. If it is determined that there is no error in the received codeword, the corresponding bit of the received codeword is output as decoded data.

The control device 16 may control the logic device module 14 to perform the message exchange process between the check nodes and the variable nodes based on the scheduling information according to, for example, a row-by-row scheduling process, a serial check X (SCX) scheduling process, or a block-serial-check X (BSCX) scheduling process. It is noted that present inventive concept is not limited to a specific scheduling approach, and, it can be implemented regardless of the scheduling approach being used.

In the row-by-row scheduling process, the check nodes are processed in series according to a few orders defined in advance. The processes of the check nodes consist of two passes. In each of the passes, neighboring variable nodes are processed in series according to an order. In pass 1 (variable node→check node), each adjacent variable node sends a message to the check node. The check node computes a new state, based on the messages. In pass 2 (check node→variable node), the check node sends a message to each adjacent variable node. The variable nodes update states thereof based on the received messages. It is also possible to use parallel row-by-row decoding where multiple checks are processed in parallel, as would be appreciated by those skilled in the art.

The SCX scheduling process is similar to the serial-check scheduling process, except that a fixed number of variable nodes are processed in parallel rather than processing the variable nodes serially. The BSCX scheduling process is similar to the SCX scheduling process; however, multiple messages are exchanged in parallel in order to speed-up the performance. In particular, in each clock cycle, messages are transmitted across the parallel edges that are expanded from the same edge. In some implementations, parallel nodes may share some properties (e.g. edges connected to other nodes), and such nodes are usually referred as a proto-node. The embodiments can be implemented regardless of the parallelism approach used.

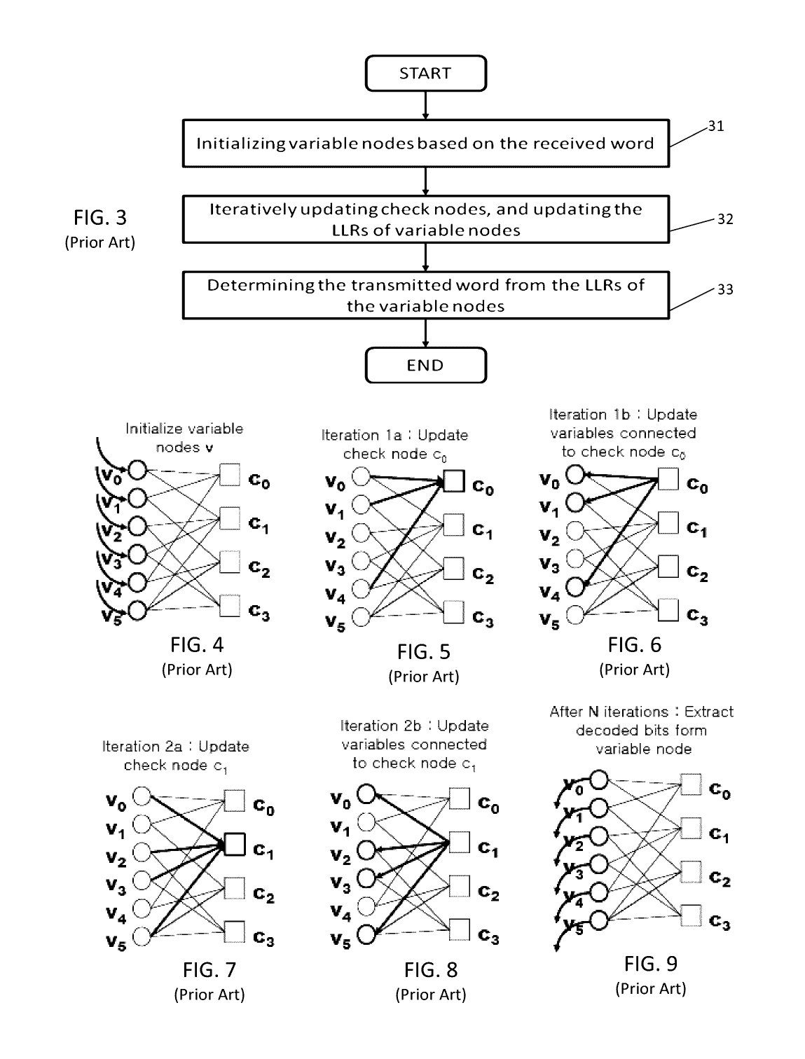

An example of a conventional row-by-row decoding process including message-passing between variable nodes V and check nodes, and updating of nodes, will be discussed with reference to the flowchart of FIG. 3 and the bipartite graphs in FIGS. 4-9. In FIG. 4, variable nodes V are initialized (step 31), e.g. with LLRs representing bits of the received codeword. At step 32 the nodes are iteratively updated including: in FIG. 5, at iteration 1a, messages are passed and check node C₀ is updated; in FIG. 6, at iteration 1b, messages are passed and the variable nodes V₀, V₁ and V₄ which are connected to check node C₀ are updated; likewise, in FIG. 7, at iteration 2a, messages are passed and check node C₁ is updated; and at iteration 2b (FIG. 8), variable nodes V₀, V₂, V₃ and V₅ which are connected to check node C₁ are updated. At step 33, after a number of iterations N (FIG. 9), the decoded bits are extracted from the variable nodes V₀-V₅.

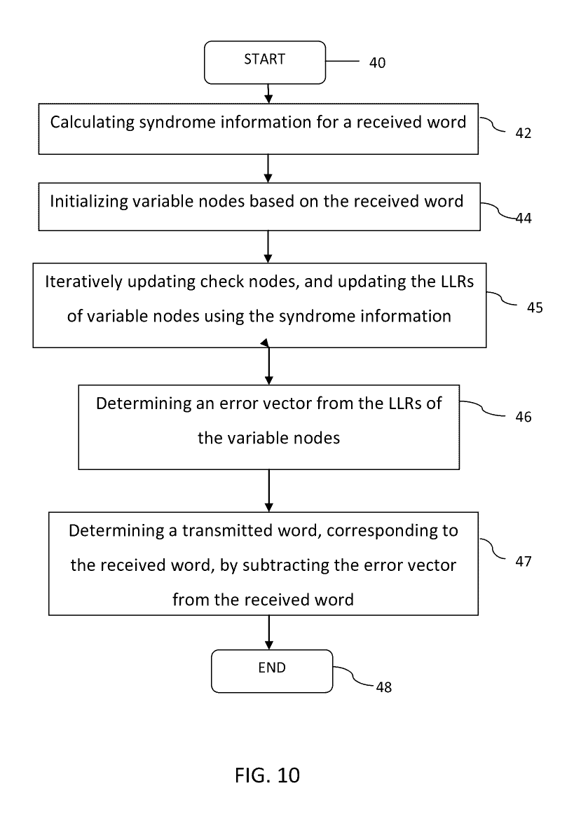

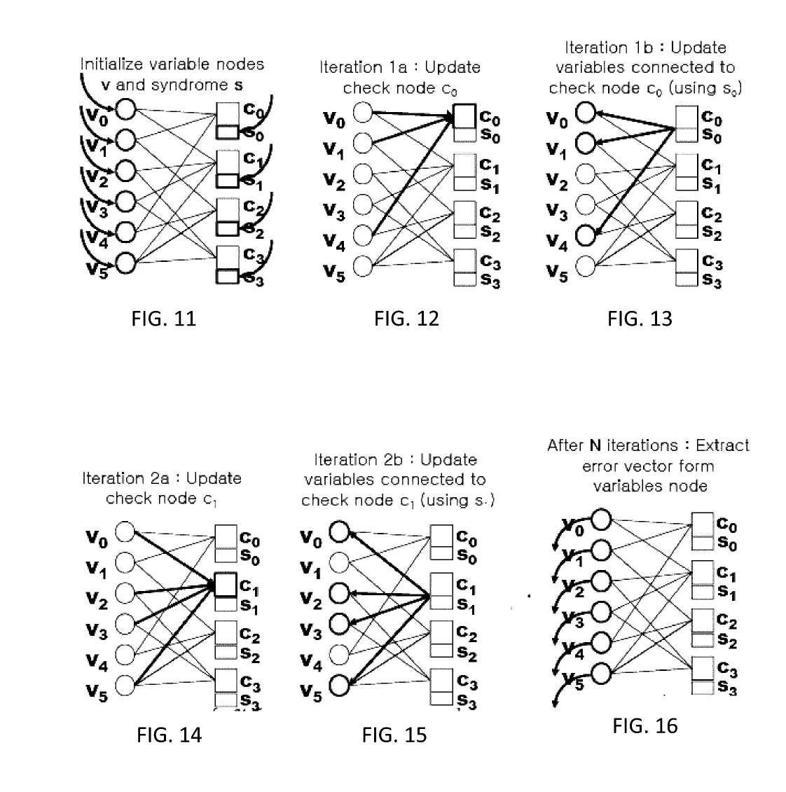

In the present inventive approach, the control device 16 controls the logic device to perform the method steps discussed below (e.g. implemented with a row-by-row decoder), with additional reference to the flowchart of FIG. 10 and the bipartite graphs in FIGS. 11-16.

The method begins (block 40) and includes calculating syndrome information S₀-S₃ for a received word at block 42, and at block 44, variable nodes V₀-V₅ are initialized based on the received word (FIG. 11). For example, each received bit of the received word may be represented by a Likelihood-Ratio (LR) or Log-Likelihood-Ratio (LLR) at a respective variable node V₀-V₅. Further, at block 45, the method includes iteratively updating check nodes C₀-C₃, and iteratively updating the LLRs of variable nodes V₀-V₅ using the syndrome information S₀-S₃.

For example, as shown in FIG. 12, at iteration 1a, messages are passed and check node C₀ is updated. In FIG. 13, at iteration 1b, messages are passed and the variable nodes V₀, V₁ and V₄ which are connected to check node C₀ are updated using syndrome information S₀. Likewise, in FIG. 14, at iteration 2a, messages are passed and check node C₁ is updated, and at iteration 2b (FIG. 15), variable nodes V₀, V₂, V₃ and V₅ which are connected to check node C₁ are updated using syndrome information S₁. After a number of iterations N (FIG. 16), an error vector is extracted from the variable nodes V₀-V₅ as set forth in block 46 which recites determining an error vector from the LLRs of the variable nodes V. At block 47, the method includes determining a transmitted word, corresponding to the received word, by subtracting the error vector from the received word, before the method ends (block 48).

So, as discussed, the received word is associated with a parity check matrix. The syndrome information S may be calculated based upon the parity check matrix, as would be appreciated by those skilled in the art. The syndrome information S may be calculated based upon S=Hy, where y is a received vector and H is the parity check matrix, and the computation is over GF(2).

In the presented inventive approach, each variable node corresponds to the associated bit error probability and not to its actual value. That is, when the iterative decoding is concluded, a vector that represents the channel error is provided.

In various embodiments, negative LLRs of the variable nodes V indicate the likelihood of an error while the conventional decoder's negative LLRs represents the likelihood of the bit having the value one. In most data-storage applications, the noisy channels generate relatively low bit error probability. In data storage as well as other digital communication channel environments, only a few LLRs will be negative (indicate an error), compared to about 50% negative LLRs at the conventional decoder (given that the codewords are drawn uniformly from the code subspace). For example, the error vector can be extracted from the variable nodes LLRs by considering a negative LLR value as an error in the corresponding received codeword bit. Subtraction of the error vector from the received codeword corresponds to an estimation of the transmitted codeword since y+e=x (or y−e=x), where x is the transmitted codeword, e is the error vector extracted from the variable nodes and y is a received vector which is defined as y=x+e and the computation is over GF(2).

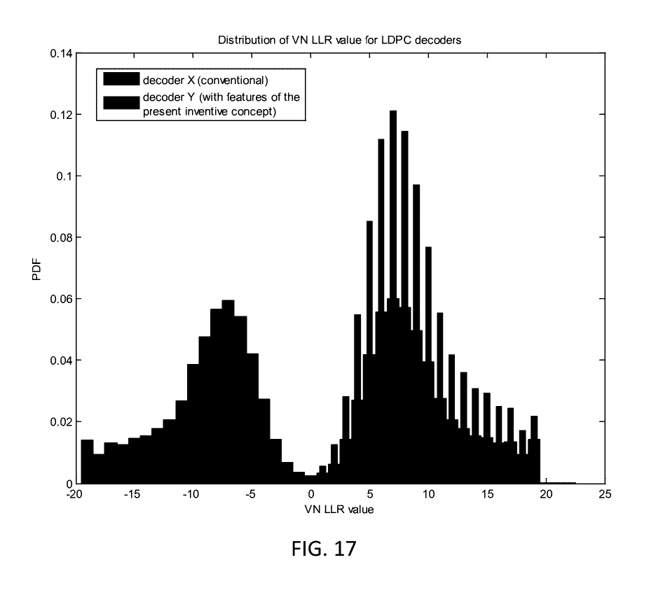

For example, in FIG. 17, the LLR distribution for a conventional decoder X, and for a decoder Y (with features of the present inventive concept) is shown for various decoding stages. It can be seen that by using the present inventive approach less than 1% of the values are negative and less than 0.1% of the values are less than or equal to −9.

So, a non-uniform quantization technique may be utilized to characterize the LLRs. More specifically, the LLRs representation need not be equally spaced over the LLR range, but may include placing more levels for some LLRs sub-ranges which are more probable than those which are not. For example, decoder Y (with features of the present inventive concept) from FIG. 17 can use a less dense grid for the negative number range such as [−19, −16, −13, −10, −8, −6, −4, −3, −2, −1] since the probability of these values are very low, while decoder X (conventional) should use a more dense grid, such as all the integers form −19 to −1, otherwise it will have performance degradation.

Also, an asymmetric dynamic range may be used to characterize the LLRs. For example, decoder X (conventional) from FIG. 17 has a symmetric dynamic range of −19 to 19 therefore 6 bits are required in order to accurately represent all the integer LLRs and to enable successful decoding. On the other hand, decoder Y (with features of the present inventive concept) can use an asymmetric dynamic range of −7 to +19 which can be represented with 5 bits and have the same decoding performance as decoder X (since the number of LLR with value −19 to −8 are negligible).

Furthermore, variable length coding may be used. LLRs with high probability can be represented using a small number of bits while LLRs with low probability may be represented using more bits. This will facilitate an efficient representation (compression) of the LLRs using the number of bits close to the entropy. For example, the entropy of LLRs in decoder X (conventional) is 5 while it is 4 in decoder Y (with features of the present inventive concept), thus, 1 bit can be saved if using the proposed invention with variable length coding.

The present inventive approach reduces the power consumption and total gate count for a hardware implemented LDPC decoder. The utilization of the syndrome information reduces the dynamic range necessary for successful decoding. Specifically, the number of bits for LLR representation (and the corresponding logic) is reduced without performance penalty (e.g. by reducing LLR from 5 bits to 4 bits).

Additionally, due to a statistical characteristic of the present decoder data, the hardware toggling rate is reduced or minimized. Negative LLRs are rare (as discussed above) and a hardware implementation which maps negative LLRs to specific bit values will significantly reduce the toggling rate of these registers. This is because these registers will be fixed for most of the decoding process, while with the conventional decoder these registers are randomly flipped for the entire decoding process. A register flip process draws much more power than a process where registers holds their value, hence the present approach should provide a more power efficient decoder. For example, consider the common two's-complement representation for the LLRs. Since the most significant bit corresponds to the sign bit, it will be zero (positive LLR value) for most of the decoding process, while with the conventional decoder it will be flipped each time the LLR sign does not equal the previous sign.

Performance (iteration count, Frame-Error-Rate and output latency) of the present decoder are not reduced compared to a conventional LDPC decoder.

The foregoing is illustrative of embodiments and is not to be construed as limiting thereof. Although a few embodiments have been described, those skilled in the art will readily appreciate that many modifications are possible in the embodiments without departing from the scope of the inventive concept as defined in the claims.

1. A decoding method for an iterative message-passing based device that includes a decoder with a memory, the method comprising:
calculating, by the decoder, syndrome information for a word received by the device;
initializing variable nodes based on the received word with each received bit of the received word being represented by a Likelihood-Ratio (LR) at a respective variable node;
iteratively updating check nodes, and updating the LRs of variable nodes using the syndrome information;
determining, by the decoder, an error vector from the LRs of the variable nodes; and
determining, by the decoder, a word transmitted to the device and corresponding to the received word, by subtracting the error vector from the received word.

2. The decoding method of claim 1,
wherein the received word is associated with a parity check matrix.

3. The decoding method of claim 2,
wherein the syndrome information is calculated based upon the parity check matrix.

4. The decoding method of claim 2,
wherein the syndrome information (S) is calculated based upon S=Hy, where y is a received vector and H is the parity check matrix, and the computation is over a Galois field of two elements (GF(2)).

5. The decoding method of claim 1,
wherein LRs of the variable nodes comprise Log Likelihood-Ratios (LLRs) and indicate the likelihood of an error.

6. The decoding method of claim 1,
wherein an asymmetric dynamic range is used to characterize the LRs.

7. The decoding method of claim 1,
wherein a non-uniform quantization technique is used to characterize the LRs.

8. The decoding method of claim 1,
wherein a variable length coding technique is used to characterize the LRs.

9. A low-density parity-check (LDPC) decoding method for an iterative message-passing based device that includes a decoder with a memory, the method comprising:
calculating, by the decoder, syndrome information for a word received by the device and an associated parity check matrix;
initializing variable nodes based on the received word;
iteratively updating check nodes, and updating variable nodes using the syndrome information;
determining, by the decoder, an error vector from the variable nodes; and
determining, by the decoder, a word transmitted to the device and corresponding to the received word, by subtracting the error vector from the received word.

10. The LDPC decoding method of claim 9,
wherein the syndrome information is calculated based upon the parity check matrix.

11. The LDPC decoding method of claim 10,
wherein the syndrome information (S) is calculated based upon S=Hy, where y is a received vector and H is the parity check matrix, and the computation is over a Galois field of two elements (GF(2)).

12. The LDPC decoding method of claim 9,
wherein a Log-Likelihood-Ratio (LLR) at a respective variable node indicates the likelihood of an error.

13. The LDPC decoding method of claim 12,
wherein an asymmetric dynamic range is used to characterize the LLRs.

14. The LDPC decoding method of claim 12,
wherein a non-uniform quantization technique is used to characterize the LLRs.

15. The LDPC decoding method of claim 12,
wherein a variable length coding technique is used to characterize the LLRs.

16. A message-passing based decoder device, comprising:
a memory configured to store states of variable nodes and check nodes in a bipartite graph;
a logic device module connected to the memory and configured to perform calculations for exchanging messages between the check nodes and the variable nodes; and
a control device configured to control the logic device module to perform the message exchanging process between the check nodes and the variable nodes based on the bipartite graph, including
calculating syndrome information for a word received by the device,
initializing variable nodes based on the received word with each received bit of the received word being represented by a Likelihood-Ratio (LR) at a respective variable node,
iteratively updating check nodes, and updating the LRs of variable nodes using the syndrome information,
determining, by the decoder, an error vector from the LRs of the variable nodes, and
determining, by the decoder, a word transmitted to the device and corresponding to the received word, by subtracting the error vector from the received word.

17. The messaging-passing based decoder of claim 16,
wherein the received word is associated with a parity check matrix, and wherein the syndrome information (S) is calculated based upon S=Hy, where y is a received vector and H is the parity check matrix, and the computation is over a Galois field of two elements (GF(2)).

18. The messaging-passing based decoder of claim 16,
wherein LRs of the variable nodes comprise Log Likelihood-Ratios (LLRs) and indicate the likelihood of an error.

19. The messaging-passing based decoder of claim 16,
wherein an asymmetric dynamic range is used to characterize the LRs.

20. The messaging-passing based decoder of claim 16,
wherein a non-uniform quantization technique is used to characterize the LRs.
